(19) United States
(12) Patent Application Publication
(10) Pub. No.: US 2011/0291181 A1
(43) Pub. Date: Dec. 1, 2011

(54) SEMICONDUCTOR DEVICE AND METHOD FOR MANUFACTURING SAME

(75) Inventors: Hiroyuki IRIFUNE, Hyogo-ken (JP); Yasuto Sumi, Hyogo-ken (JP); Kiyoshi Kimura, Hyogo-ken (JP); Hiroshi Ohta, Hyogo-ken (JP)

(73) Assignee: Kabushiki Kaisha Toshiba, Tokyo (JP)

(21) Appl. No.: 13/149,345

(22) Filed: May 31, 2011

(30) Foreign Application Priority Data
May 31, 2010 (JP) 2010-123946

(51) Int. Cl. H01L 29/78; H01L 21/336

(52) U.S. Cl. 257/328; 438/268; 257/E29.256; 257/E21.418

(57) ABSTRACT

According to one embodiment, a semiconductor device including a cell region and a terminal region includes a first semiconductor region of a first conductivity type, semiconductor pillars of the first and a second conductivity type, a second semiconductor region of the second conductivity type, and a third semiconductor region of the first conductivity type. The semiconductor pillars of the first and second conductivity type are and arranged alternately on the first semiconductor region. The second semiconductor region is provided on the semiconductor pillar of the second conductivity type. The third semiconductor region is provided on the second semiconductor region. A semiconductor pillar other than a semiconductor pillar most proximal to the terminal region is provided in a stripe configuration. The semiconductor pillar most proximal to the terminal region includes regions having a high and a low impurity concentration. The regions are provided alternately.

### CROSS-REFERENCE TO RELATED APPLICATIONS

This application is based upon and claims the benefit of priority from the prior Japanese Patent Application No. 2010-123946, filed on May 31, 2010; the entire contents of which are incorporated herein by reference.

### FIELD

Embodiments described herein relate generally to a semiconductor device and a method for manufacturing the same.

### BACKGROUND

In a vertical power MOSFET (Metal-Oxide-Semiconductor Field-Effect Transistor), a breakdown voltage is applied not only to the main cell region that conducts current but also to the terminal region outside the cell region. Therefore, the design of the element terminal region is indispensable to realize the breakdown voltage necessary in the design of the entire element. In a power MOSFET having a super junction structure, and particularly in the case where the super junction structure is not disposed in the terminal region, the charge balance (equivalent amounts of charge) at the boundary between the cell region and the terminal region is important.

To maintain the charge balance in the semiconductor pillars of the super junction structure that have stripe configurations, the width of the semiconductor pillar of the outermost edge is ½ of the width of the adjacent semiconductor pillar. However, in the semiconductor device having the super junction structure, the process margin of the masks (the resist masks, etc.) used when forming the semiconductor pillars decreases as the width of the semiconductor pillars becomes narrow.

### BRIEF DESCRIPTION OF THE DRAWINGS

FIGS. 1A and 1B are schematic views illustrating the configuration of a semiconductor device according to a first embodiment;

FIG. 2 is a schematic plan view of the semiconductor device according to the first embodiment;

FIGS. 3A and 3B are schematic plan views illustrating the reference example;

FIG. 4 is a flowchart illustrating a method for manufacturing the semiconductor device according to a second embodiment;

FIG. 5A to FIG. 6C are schematic views illustrating profiles of the impurity concentration of the semiconductor pillars;

FIG. 7 is a schematic plan view illustrating another example of the first embodiment;

FIG. 8 is a schematic cross-sectional view illustrating the configuration of a semiconductor device according to a third embodiment;

FIG. 9 is a schematic cross-sectional view illustrating the configuration of a semiconductor device according to a fourth embodiment; and

FIG. 10 is a schematic cross-sectional view illustrating the configuration of a semiconductor device according to a fifth embodiment.

### DETAILED DESCRIPTION

In general, according to one embodiment, a semiconductor device includes a cell region configured to conduct current and a terminal region provided around the cell region. The device includes a first semiconductor region of a first conductivity type, a semiconductor pillar of the first conductivity type and a semiconductor pillar of a second conductivity type, a first main electrode, a second semiconductor region of the second conductivity type, a third semiconductor region of the first conductivity type, a second main electrode, and a control electrode. The semiconductor pillar of the first conductivity type and the semiconductor pillar of the second conductivity type are provided on the first semiconductor region in the cell region and arranged alternately along a first direction parallel to one major surface of the first semiconductor region. The first main electrode is provided on one other major surface side of the first semiconductor region. The second semiconductor region of the second conductivity type is provided in a surface of the semiconductor pillar of the second conductivity type. The third semiconductor region of the first conductivity type is provided on a surface side of the second semiconductor region. The second main electrode is connected to the second semiconductor region and the third semiconductor region. The control electrode is provided with an interposed gate insulating film on the second semiconductor region, the third semiconductor region, and the semiconductor pillar of the first conductivity type. A semiconductor pillar is provided in a stripe configuration extending in a second direction parallel to the one major surface of the first semiconductor region and orthogonal to the first direction. The semiconductor pillar provided in the stripe configuration is selected from the semiconductor pillar of the first conductivity type and the semiconductor pillar of the second conductivity type other than a semiconductor pillar most proximal to the terminal region. The semiconductor pillar most proximal to the terminal region includes a region having a relatively high impurity concentration and a region having a relatively low impurity concentration. The region having the high impurity concentration and the region having the low impurity concentration are provided alternately along the second direction.

In general, according to another embodiment, a method is disclosed for manufacturing a semiconductor device including a cell region configured to conduct current and a terminal region provided around the cell region. The method can include forming a first semiconductor region of a first conductivity type. The method can include forming a high-resistance region on one major surface of the first semiconductor region. The method can include forming a first impurity implantation region and a second impurity implantation region in the high-resistance region of the cell region. The first impurity implantation region includes an implanted impurity of the first conductivity type, and the second impurity implantation region includes an implanted impurity of a second conductivity type. The first impurity implantation region and the second impurity implantation region are formed alternately along a first direction parallel to the one major surface of the first semiconductor region. The method can include forming a semiconductor pillar of the first conductivity type and a semiconductor pillar of the second conductivity type by causing the first impurity implantation region to communicate along a direction perpendicular to the one major surface of the first semiconductor region and the second impurity implantation region to communicate along the direction perpendicular to the one major surface of the first semiconductor region by performing thermal diffusion after repeating the forming of the high-resistance region and the alternate forming of the first impurity implantation region and the second impurity implantation region. The method can include forming a second semiconductor region of the second conductivity type selectively in a surface of the semiconductor pillar of the second conductivity type. The method can include forming a third semiconductor region of the first conductivity type selectively in a surface of the second semiconductor region. The method can include forming a control electrode with an interposed gate insulating film on the second semiconductor region, the third semiconductor region, and the semiconductor pillar of the first conductivity type. The method can include forming a first main electrode on one other major surface side of the first semiconductor region. In addition, the method can include connecting a second main electrode to the second semiconductor region and the third semiconductor region. The alternate forming of the first impurity implantation region and the second impurity implantation region includes forming an impurity implantation region in a stripe configuration extending in a second direction parallel to the one major surface of the first semiconductor region and orthogonal to the first direction. The impurity implantation region having the stripe configuration is selected from the first impurity implantation region and the second impurity implantation region other than an impurity implantation region most proximal to the terminal region. In addition, the alternate forming includes forming a region having a relatively high impurity concentration and a region having a relatively low impurity concentration in the impurity implantation region most proximal to the terminal region. The region having the high impurity concentration and the region having the low impurity concentration are formed alternately along the first direction.

Various embodiments will be described hereinafter with reference to the accompanying drawings.

The drawings are schematic or conceptual; and the relationships between the thicknesses and widths of portions, the proportional coefficients of sizes among portions, etc., are not necessarily the same as the actual values thereof. Further, the dimensions and the proportional coefficients may be illustrated differently among the drawings, even for identical portions.

In the specification and the drawings of the application, components similar to those described in regard to a drawing thereinabove are marked with like reference numerals, and a detailed description is omitted as appropriate.

In the description recited below, a specific example in which the first conductivity type is an n type and the second conductivity type is a p type is illustrated as one example.

In the description recited below, the first direction, which is one direction parallel to one major surface 11a of an n⁺ drain layer (a first semiconductor region) 11, is taken as an X direction. The second direction, which is parallel to the major surface 11a and orthogonal to the first direction (the X direction), is taken as a Y direction. A direction perpendicular to the major surface 11a is taken as the third direction (a Z direction).

### First Embodiment

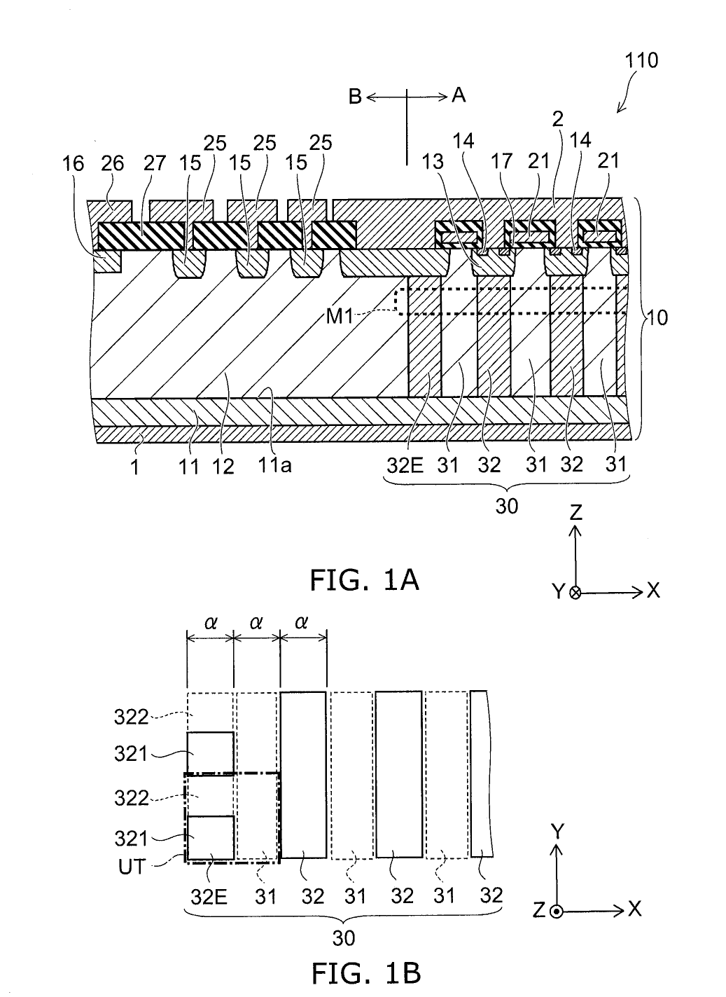

FIGS. 1A and 1B are schematic views illustrating the configuration of a semiconductor device according to a first embodiment.

FIG. 1A is a schematic cross-sectional view centered on the boundary between a cell region and a terminal region of the semiconductor device 110 according to the first embodiment.

FIG. 1B is a schematic plan view of the semiconductor pillar unit illustrated by a broken-line box M1 of FIG. 1A.

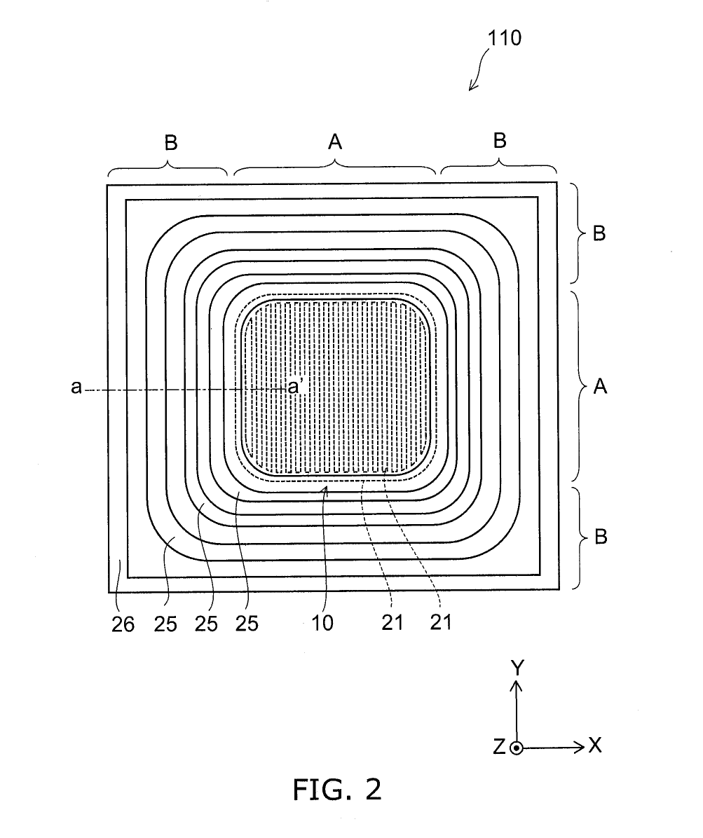

FIG. 2 is a schematic plan view of the semiconductor device according to the first embodiment.

First, the planar configuration of the semiconductor device 110 according to the embodiment will be described based on FIG. 2.

As illustrated in FIG. 2, the semiconductor device 110 includes a cell region A and a terminal region B provided around the cell region A. The cell region A includes an element unit 10 that functions as a semiconductor element. A gate electrode 21 of the element unit 10 is formed in a stripe configuration along the Y direction inside the cell region A. Multiple gate electrodes 21 are disposed at a prescribed spacing along the X direction inside the cell region A.

A guard ring electrode 25 is provided in the terminal region B. The guard ring electrode 25 is provided around the cell region A. The guard ring electrode 25 may be provided multiply if necessary. An EQPR (Equivalent Potential Ring) electrode 26 is provided on the outer side of the outermost guard ring electrode 25.

In the semiconductor device 110 according to the embodiment, the semiconductor pillars of the boundary portion between the cell region A and the terminal region B are distinctive.

The distinctive portions of the semiconductor device 110 according to the embodiment will now be described based on FIGS. 1A and 1B.

FIG. 1A is a schematic cross-sectional view along line a-a′ of FIG. 2.

The semiconductor device 110 illustrated in FIGS. 1A and 1B functions as a MOSFET.

The element unit 10 includes the n⁺ drain layer (the first semiconductor region) 11, the semiconductor pillar unit 30 in which an n-type semiconductor pillar 31 and a p-type semiconductor pillar 32 are provided alternately along the X direction, a drain electrode (a first main electrode) 1 provided on one other major surface side of the n⁺ drain layer 11, a p-type base layer (the second semiconductor region) 13 provided selectively in the surface of the semiconductor pillar 32, an n-type source layer (a third semiconductor region) 14 provided selectively in the surface of the p-type base layer 13, a source electrode (a second main electrode) 2 connected to the p-type base layer 13 and the n-type source layer 14, and the gate electrode (the control electrode) 21 provided with an interposed gate insulating film 17.

The semiconductor pillar unit 30 of the semiconductor device 110 functions as a super junction of the element unit 10. In the semiconductor pillar unit 30, the semiconductor pillars 31 and 32 other than a semiconductor pillar 32E most proximal to the terminal region B are provided in stripe configurations along the Y direction.

On the other hand, the semiconductor pillar 32E most proximal to the terminal region B includes a region having a relatively high impurity concentration (a high-concentration region 321) and a region having a relatively low impurity concentration (a low-concentration region 322). Herein, the impurity concentration refers to the number of carriers per unit volume. The high-concentration region 321 and the low-concentration region 322 are disposed alternately along the Y direction.

In the terminal region B, a high-resistance region 12 is provided on the one major surface of the n⁺ drain layer 11; and a guard ring 15 is provided in the high-resistance region 12. Other than a non-doped region, the high-resistance region 12 also includes a region into which a very small amount of an impurity is implanted. The guard ring 15 is provided, for example, multiply. A guard ring electrode 25 is connected to each of the guard rings 15. The guard ring electrodes 25 are separated from each other by an inter-layer insulating film 27. An EQPR 16 is provided on the outer side of the outermost guard ring 15. An EQPR electrode 26 is connected to the EQPR 16. The EQPR electrode 26 and the guard ring electrode 25 are separated from each other by the inter-layer insulating film 27.

The high-concentration region 321 and the low-concentration region 322 are disposed alternately along the Y direction as the semiconductor pillar 32E most proximal to the terminal region B in the semiconductor device 110 according to the embodiment. Thereby, the entire semiconductor pillar 32E can have an impurity concentration lower than that of the case where the semiconductor pillars have a uniform impurity concentration distribution. In other words, the charge balance between the semiconductor pillar 32E and the semiconductor pillar 31 adjacent thereto is adjusted by the balance between the high-concentration region 321 and the low-concentration region 322.

Because the impurity concentration of the semiconductor pillar 32E most proximal to the terminal region B can be adjusted without depending on the width along the X direction in the semiconductor device 110 according to the embodiment, the charge balance with the adjacent semiconductor pillar 31 can be maintained and the decrease of the process margin can be suppressed.

Although FIGS. 1A and 1B are schematic cross-sectional views along line a-a′ of FIG. 2, the terminal region B on the side of the cell region A opposite to the position of line a-a′ also has a similar configuration. That is, the configuration at the terminal region B of the opposite side is a configuration in which the configuration of the schematic cross-sectional views of FIGS. 1A and 1B is symmetrically reflected around a Y-direction axis.

### Reference Example

A reference example will now be described.

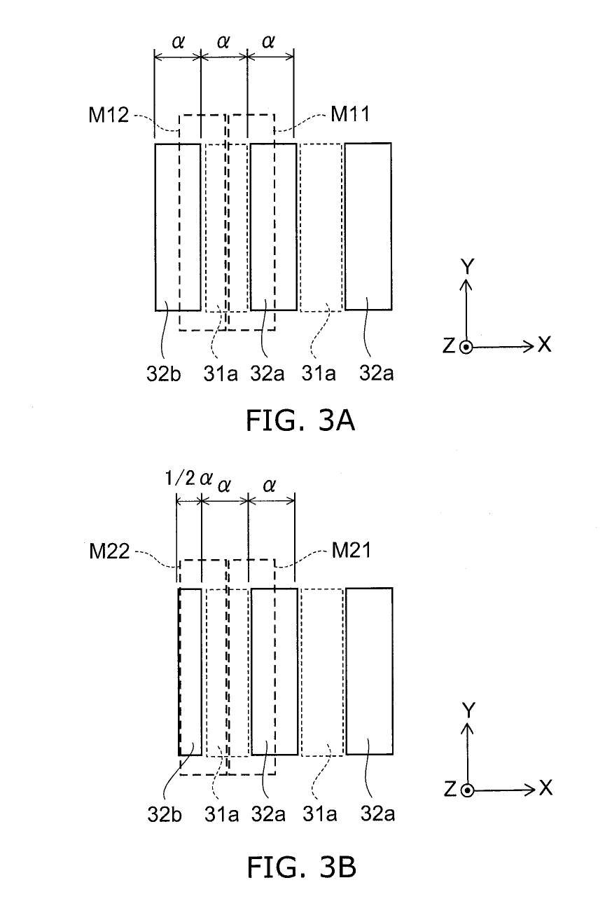

FIGS. 3A and 3B are schematic plan views illustrating the reference example.

FIGS. 3A and 3B illustrate a disposition example of the semiconductor pillars according to the reference example.

FIG. 3A illustrates the case where a width a of the n-type semiconductor pillar 31 along the X direction is equal to a width α of the p-type semiconductor pillar 32 along the X direction. The impurity implantation amounts of the semiconductor pillars 31 and 32 are equal. In this case, the charge balance is maintained between semiconductor pillars 31a and 32a other than a semiconductor pillar 32b most proximal to the terminal region (referring to a broken-line box M11 in the drawing). However, the charge balance is not maintained between the semiconductor pillar 32b most proximal to the terminal region and the semiconductor pillar 31a adjacent thereto (referring to a broken-line box M12 in the drawing).

FIG. 3B illustrates the case where the width of the semiconductor pillar 32b most proximal to the terminal region is ½ of the width of the semiconductor pillars 31a and 32a other than the semiconductor pillar 32b to maintain the charge balance in the terminal region. In this case, the charge balance is maintained similarly to the case illustrated in FIG. 3A between the semiconductor pillars 31a and 32a (referring to a broken-line box M21 in the drawing). On the terminal region side as well, the charge balance is maintained between the semiconductor pillar 32b and the semiconductor pillar 31a adjacent thereto (referring to a broken-line box M22 in the drawing) because the width of the semiconductor pillar 32b is ½ of the width a of the semiconductor pillars 31a and 32a other than the semiconductor pillar 32b, i.e., ½α.

However, in the case where the width of the semiconductor pillar 32b is halved, the process margin along the X direction of the mask (the resist mask, etc.) used when forming the semiconductor pillar 32b decreases to ½ of the process margin along the X direction of the mask used when forming the semiconductor pillars 31a and 32b.

On the other hand, in the semiconductor device 110 according to the embodiment as illustrated in FIG. 1B, the high-concentration region 321 and the low-concentration region 322 are disposed alternately along the Y direction as the semiconductor pillar 32E of the super junction most proximal to the terminal region B. Therefore, the charge balance can be maintained without making the width of the semiconductor pillar 32E along the X direction narrower than the width along the X direction of each of the semiconductor pillars 31 and 32 of the semiconductor pillar unit 30.

The width along the X direction of the semiconductor pillar 32E illustrated in FIG. 1B is equal to the width a along the X direction of each of the semiconductor pillars 31 and 32 of the semiconductor pillar unit 30. Here, the impurity concentration of the high-concentration region 321 is equal to the impurity concentration of the semiconductor pillar 32. The low-concentration region 322 may be, for example, the high-resistance region 12, a non-doped region into which an impurity is not implanted, a region into which a very small amount of an impurity is implanted, etc. Accordingly, in the case where the ratio of the pattern surface area of the high-concentration region 321 on the XY plane to the pattern surface area of the adjacent semiconductor pillar 31 on the XY plane is 0.5:1, the impurity amount (the total number of carriers) of the semiconductor pillar 32E becomes ½ of the impurity amount of the adjacent semiconductor pillar 31.

Thereby, the charge balance between the semiconductor pillar 32E and the semiconductor pillar 31 adjacent thereto can be maintained even in the case where the width of the semiconductor pillar 32E along the X direction is equal to the width a along the X direction of each of the semiconductor pillars 31 and 32 of the semiconductor pillar unit 30. That is, the charge balance can be maintained even in the case where the width along the X direction of the semiconductor pillar 32E most proximal to the terminal region B resulting from the process margin is equal to the width along the X direction of the semiconductor pillars 31 and 32 other than the semiconductor pillar 32E. Therefore, the decrease of the process margin of the semiconductor pillar 32E can be suppressed while the charge balance is maintained.

In the semiconductor pillar 32E illustrated in FIGS. 1A and 1B, the pitch of the high-concentration region 321 along the Y direction is equal to the pitch of the low-concentration region 322 along the Y direction. Thus, because the high-concentration region 321 and the low-concentration region 322 are disposed alternately with equal pitches, the difference between high and low concentrations of the high-concentration region 321 and the low-concentration region 322 can be reduced easily by causing the impurity to diffuse when forming the semiconductor pillar 32E.

The high-concentration region 321, which has a substantially square pattern configuration in the XY plane, is disposed periodically in the semiconductor pillar 32E illustrated in FIG. 1B. Here, it is sufficient for the surface area ratio of the semiconductor pillar 32E to the semiconductor pillar 31 in a unit cell UT to be 0.5:1, where the unit cell UT is the region up to the next repeated high-concentration region 321. Accordingly, if the high-concentration region 321 and the low-concentration region 322 are finally linked by the diffusion, it is unnecessary for the pattern configuration (the XY planar configuration) of the high-concentration region 321 to be substantially square.

### Second Embodiment

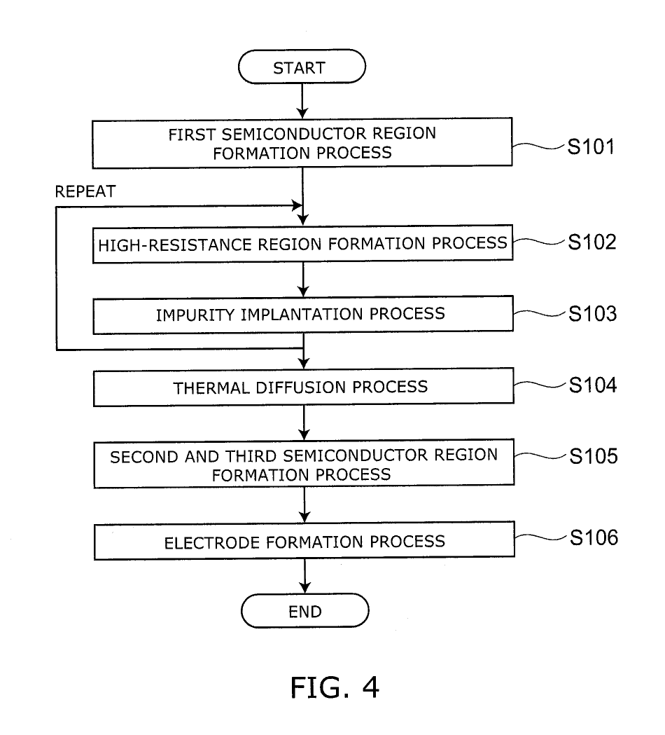

FIG. 4 is a flowchart illustrating a method for manufacturing the semiconductor device according to a second embodiment.

The method for manufacturing the semiconductor device according to the embodiment includes a first semiconductor region formation process (step S101), a high-resistance region formation process (step S102), an impurity implantation process (step S103), a thermal diffusion process (step S104), a second and third semiconductor region formation process (step S105), and an electrode formation process (step S106).

Herein, the semiconductor pillar unit 30 is formed by repeating the high-resistance region formation process (step S102) and the impurity implantation process (step S103) and then performing the thermal diffusion process (step S104).

Each of the processes will now be described in order.

First, in the first semiconductor region formation process (step S101), the n⁺ drain layer (the first semiconductor region) 11 is formed in the cell region A and the terminal region B. Then, in the high-resistance region formation process (step S102), the high-resistance region 12 is formed in the one major surface 11a of the n⁺ drain layer 11.

Then, the impurity implantation process (step S103) is performed. In the impurity implantation process, first, a resist mask is formed in which openings are provided only at the positions where the n-type semiconductor pillars 31 are formed. Continuing, for example, P (phosphorus) is implanted through the openings of the resist mask. Thereby, the n-type impurity implantation region (the first impurity implantation region) is formed. The n-type impurity implantation region is formed corresponding to the positions where the n-type semiconductor pillars 31 are formed. In other words, the n-type impurity implantation region is formed in a stripe configuration along the Y direction at a constant spacing along the X direction. Subsequently, the resist mask is removed.

Then, a resist mask is formed in which openings are provided only at the positions where the p-type semiconductor pillar 32 and the high-concentration region 321 of the semiconductor pillar 32E are formed. Continuing, for example, B (boron) is implanted through the openings of the resist mask. Thereby, the p-type impurity implantation region (the second impurity implantation region) is formed and the impurity implantation region that becomes the high-concentration region 321 is formed.

Continuing, the high-resistance region formation process (step S102) and the impurity implantation process (step S103) are repeated a prescribed number of times. Thereby, the n-type impurity implantation region, the p-type impurity implantation region, and the impurity implantation region that becomes the high-concentration region 321 are stacked respectively onto themselves in the Z direction.

Then, in the thermal diffusion process (step S104), heating is performed at a prescribed temperature to diffuse the implanted impurities. Thereby, the impurity implantation regions communicate with themselves in the Z direction to form the n-type semiconductor pillar 31, the p-type semiconductor pillar 32, and the semiconductor pillar 32E.

Although the formation of the semiconductor pillar 32E, which has an impurity implantation region different from that of the semiconductor pillar 32, uses only a different opening of the resist mask during the impurity implantation, the same manufacturing process is used. The width along the X direction of the opening of the resist mask used when forming the semiconductor pillar 32E is equal to the widths along the X direction of the openings of the resist masks used when forming the semiconductor pillars 31 and 32. Accordingly, the decrease of the process margin of the resist mask along the X direction is suppressed.

As the second and third semiconductor region formation process (step S105), the p-type base layer (the second semiconductor region) 13 is formed selectively in the surface of the p-type semiconductor pillar 32; and the n-type source layer (the third semiconductor region) 14 is formed selectively in the surface of the p-type base layer 13.

Subsequently, as the electrode formation process (step S106), the drain electrode (the first main electrode) 1 is formed on the one other major surface side of the n⁺ drain layer 11; the gate electrode (the control electrode) 21 is formed with the interposed gate insulating film 17 on the semiconductor pillar 31, the p-type base layer 13, and the n-type source layer 14; and the source electrode (the second main electrode) 2 is connected to the p-type base layer 13 and the n-type source layer 14. Thereby, the semiconductor device 110 is completed.

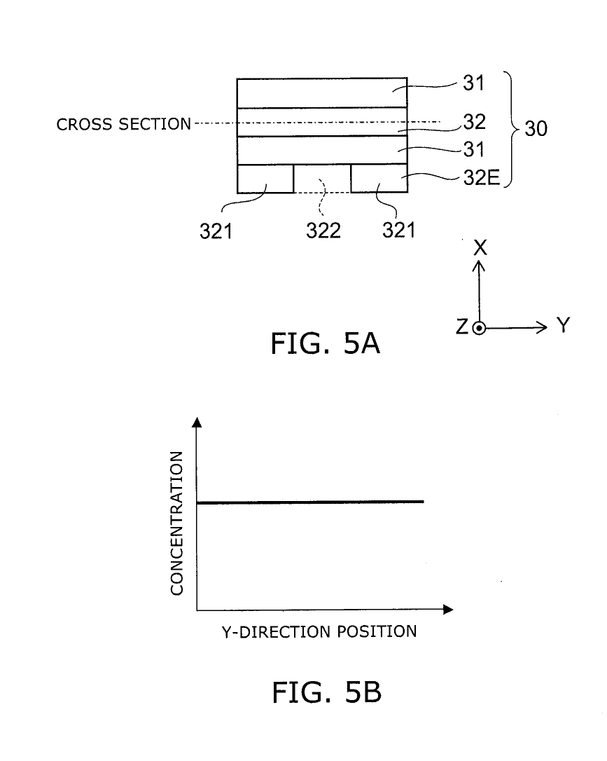

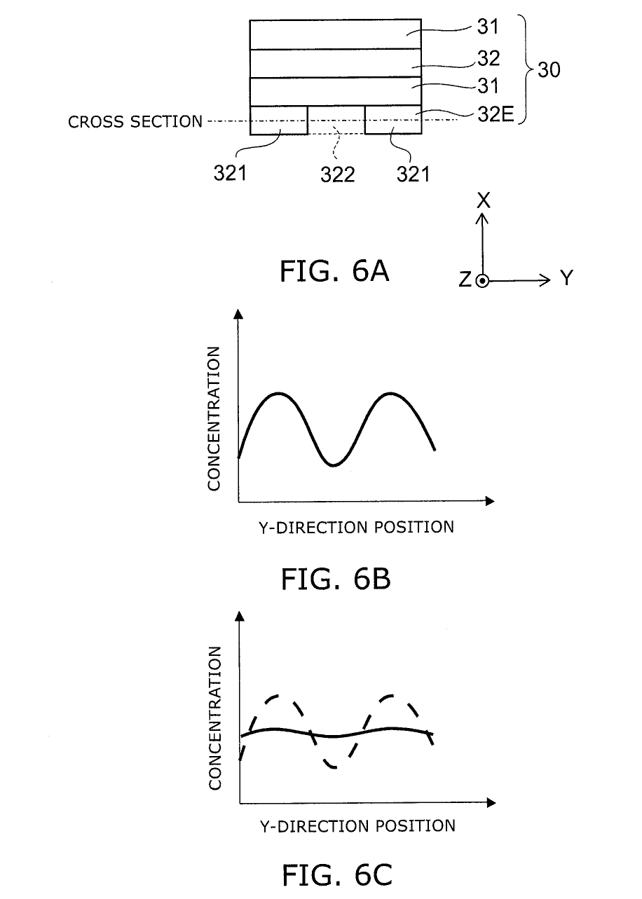

FIG. 5A to FIG. 6C are schematic views illustrating profiles of the impurity concentration of the semiconductor pillars.

FIG. 5A is a schematic plan view of the semiconductor pillars in the XY plane.

FIG. 5B illustrates the profile of the impurity concentration of the semiconductor pillar 32 illustrated in FIG. 5A at a cross section along the Y direction. In the graph of FIG. 5B, the horizontal axis illustrates the position along the Y direction; and the vertical axis illustrates the impurity concentration. In the semiconductor pillar 32, the impurity concentration is substantially constant along the Y direction.

FIG. 6A is a schematic plan view of the semiconductor pillars in the XY plane.

FIGS. 6B and 6C illustrate the profile of the impurity concentration of the semiconductor pillar 32E illustrated in FIG. 6A at a cross section along the Y direction. In the graph of FIGS. 6B and 6E, the horizontal axis illustrates the position along the Y direction; and the vertical axis illustrates the impurity concentration.

Here, FIG. 6B illustrates the profile of the concentration directly after the impurity implantation. Directly after the impurity implantation, the concentration difference between the high-concentration region 321 and the low-concentration region 322 is large.

FIG. 6C illustrates the profile of the concentration of the impurity after thermal diffusion is performed. By performing the thermal diffusion, the profile of the concentration illustrated by the broken line in the drawing changes to the profile of the concentration illustrated by the solid line in the drawing; and the concentration difference between the high-concentration region 321 and the low-concentration region 322 is reduced.

By alternately providing the high-concentration region 321 and the low-concentration region 322 in the semiconductor pillar 32E, the impurity implantation amount of the semiconductor pillar 32E is ½ of the impurity implantation amount of the semiconductor pillars 31 and 32 of the semiconductor pillar unit 30.

In other words, in the case where the pattern surface area ratio of the high-concentration region 321 to the adjacent semiconductor pillar 31 is 0.5:1, the impurity implantation amount of the semiconductor pillar 32E is ½ of the impurity implantation amount of the adjacent semiconductor pillar 31. Thereby, the charge balance between the semiconductor pillar 32E and the semiconductor pillar 31 adjacent thereto can be maintained even in the case where the width of the semiconductor pillar 32E along the X direction is equal to the width along the X direction of each of the semiconductor pillars 31 and 32 of the semiconductor pillar unit 30. The impurity concentration after the diffusion of the semiconductor pillar 32E is equal to the impurity concentration of the semiconductor pillar 32b of the case where the width illustrated in FIG. 3B is halved.

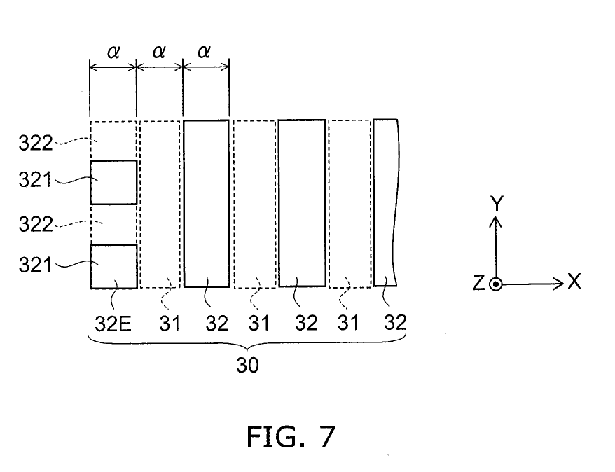

FIG. 7 is a schematic plan view illustrating another example of the first embodiment.

FIG. 7 is a schematic plan view of the semiconductor pillar unit of the semiconductor device.

In this example, the semiconductor pillar 32E most proximal to the terminal region and the semiconductor pillars 31 and 32 other than the semiconductor pillar 32E are provided. Thereof, the semiconductor pillars 31 and 32 are formed in stripe configurations along the Y direction. On the other hand, the semiconductor pillar 32E includes the high-concentration region 321 and the low-concentration region 322.

Here, the semiconductor pillar 31 is the p type which is the second conductivity type. The semiconductor pillar 32 is the n type which is the first conductivity type. The high-concentration region 321 of the semiconductor pillar 32E is the n type, which is the conductivity type (the first conductivity type) opposite to the conductivity type (the second conductivity type) of the adjacent semiconductor pillar 31.

Thus, even in the case where the conductivity type is opposite to that of the semiconductor pillar unit illustrated in FIGS. 1A and 1B, the decrease of the process margin of the semiconductor pillars can be suppressed while the charge balance is maintained.

### Third Embodiment

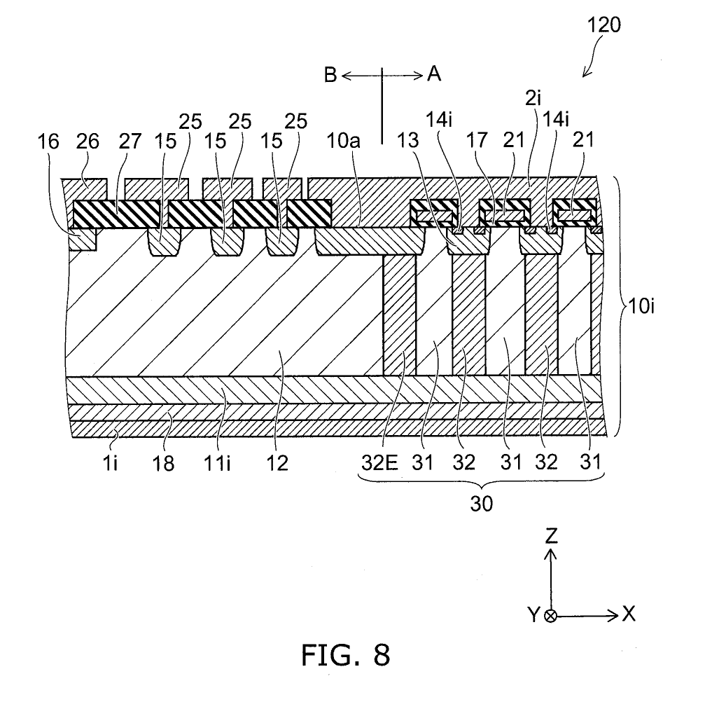

FIG. 8 is a schematic cross-sectional view illustrating the configuration of a semiconductor device according to a third embodiment.

As illustrated in FIG. 8, the semiconductor device 120 according to the embodiment functions as an IGBT (Insulated Gate Bipolar Transistor). An element unit 10i has an IGBT configuration.

The element unit 10i includes: an n⁺ buffer layer (a first semiconductor region) 11i; the semiconductor pillar unit 30 including the n-type semiconductor pillar 31 and the p-type semiconductor pillar 32 provided alternately along the X direction; a collector electrode (a first main electrode) 1i provided on one other major surface side of the n⁺ buffer layer 11i; the p-type base layer (the second semiconductor region) 13 formed selectively in the surface of the semiconductor pillar 32; an n-type emitter layer (a third semiconductor region) 14i provided selectively in the surface of the p-type base layer 13; a p-type collector layer (a fourth semiconductor region) 18 provided in the one other major surface of the n⁺ buffer layer 11i; an emitter electrode (a second main electrode) 2i connected to the p-type base layer 13 and the n-type emitter layer 14i; and the gate electrode (the control electrode) 21 provided with the interposed gate insulating film 17.

The semiconductor pillar unit 30 of the semiconductor device 110 functions as the super junction of the element unit 10i. In the semiconductor pillar unit 30, the semiconductor pillars 31 and 32 other than the semiconductor pillar 32E most proximal to the terminal region B are provided in stripe configurations along the Y direction.

On the other hand, the semiconductor pillar 32E most proximal to the terminal region B includes a region (the high-concentration region 321) having a relatively high impurity concentration and a region (the low-concentration region 322) having a relatively low impurity concentration. Herein, the impurity concentration refers to the number of carriers per unit volume. The high-concentration region 321 and the low-concentration region 322 are disposed alternately along the Y direction.

In the terminal region B, the high-resistance region 12 is provided on one major surface of the n⁺ buffer layer 11i; and the guard ring 15 is provided in the high-resistance region 12. The guard ring 15 is provided, for example, multiply. The guard ring electrode 25 is connected to each of the guard rings 15. The guard ring electrodes 25 are separated from each other by the inter-layer insulating film 27. The EQPR 16 is provided on the outer side of the outermost guard ring 15. The EQPR electrode 26 is connected to the EQPR 16. The EQPR electrode 26 and the guard ring electrode 25 are separated from each other by the inter-layer insulating film 27.

Because the high-concentration region 321 and the low-concentration region 322 are disposed alternately along the Y direction as the semiconductor pillar 32E most proximal to the terminal region B in the semiconductor device 110 according to the embodiment, the entire semiconductor pillar 32E can have an impurity concentration lower than that of the case where the semiconductor pillars have a uniform impurity concentration distribution. In other words, the charge balance between the semiconductor pillar 32E and the semiconductor pillar 31 adjacent thereto is adjusted by the balance between the high-concentration region 321 and the low-concentration region 322. Therefore, the decrease of the process margin of the semiconductor pillars can be suppressed while the charge balance is maintained.

### Fourth Embodiment

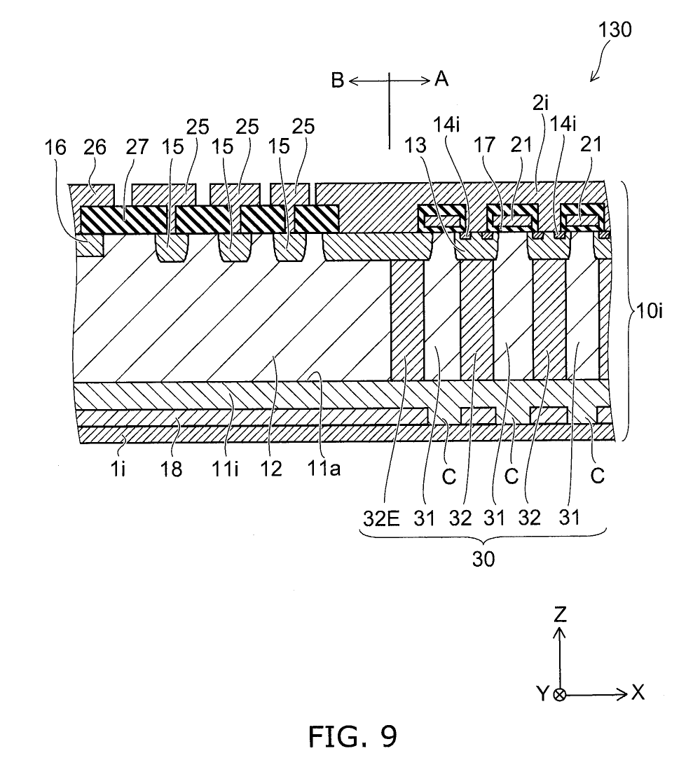

FIG. 9 is a schematic cross-sectional view illustrating the configuration of a semiconductor device according to a fourth embodiment.

As illustrated in FIG. 9, the semiconductor device 130 according to the embodiment functions as a reverse conducting IGBT.

The semiconductor device 130 illustrated in FIG. 9 differs from the semiconductor device 120 illustrated in FIG. 8 in that the n⁺ buffer layer 11i is electrically connected to the collector electrode 1i at a portion C of the p-type collector layer 18.

In the semiconductor device 130, when a voltage that is positive with respect to the emitter electrode 2i is applied to the gate electrode 21, the semiconductor device 130 operates as an IGBT. On the other hand, when the potential on the emitter electrode 2i side is higher than the potential on the collector electrode 1i side, the semiconductor device 130 operates as a diode.

In semiconductor device 130 according to the embodiment as well, similarly to the semiconductor devices 110 and 120, the charge balance between the semiconductor pillar 31 and the semiconductor pillar 32E is adjusted by the balance between the high-concentration region 321 and the low-concentration region 322 of the semiconductor pillar 32E. Therefore, the decrease of the process margin of the semiconductor pillars can be suppressed while the charge balance is maintained.

### Fifth Embodiment

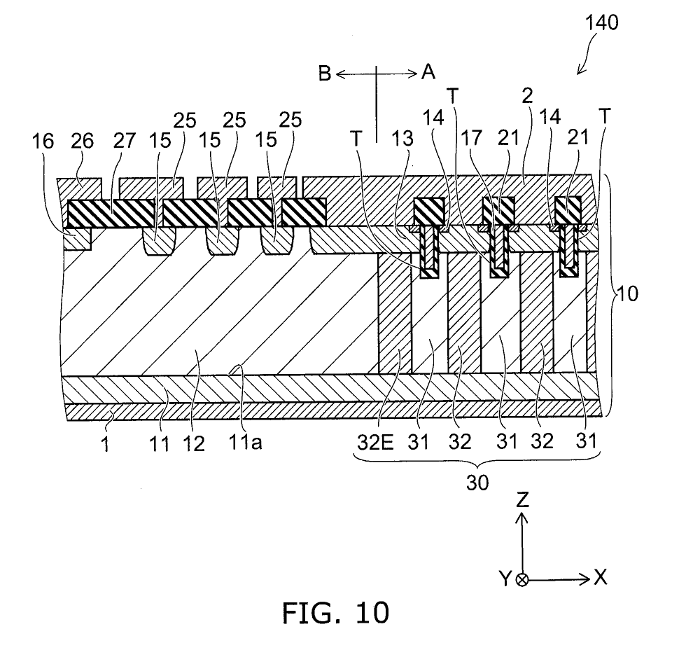

FIG. 10 is a schematic cross-sectional view illustrating the configuration of a semiconductor device according to a fifth embodiment.

As illustrated in FIG. 10, the gate electrode 21 is formed inside a trench T in the semiconductor device 140 according to the embodiment.

In other words, the trench T is provided along the Z direction in the semiconductor pillar 31. That is, the trench T is provided along the Z direction in the n-type semiconductor pillar 31, the p-type base layer 13, and the n-type source layer 14. The gate electrode 21 is formed with the interposed gate insulating film 17 inside the trench T. The n-type source layer 14 is provided on both sides of the trench T of the p-type base layer 13. The n-type source layer 14 is connected to the source electrode 2. Thereby, the semiconductor device 140 has a trench gate structure.

In the semiconductor device 140 according to the embodiment as well, similar to the semiconductor devices 110, 120, and 130, the charge balance between the semiconductor pillar 31 and the semiconductor pillar 32E is adjusted by the balance between the high-concentration region 321 and the low-concentration region 322 of the semiconductor pillar 32E. Therefore, the decrease of the process margin of the semiconductor pillars can be suppressed while the charge balance is maintained.

According to the embodiment as described above, a semiconductor device and a method for manufacturing the same are provided in which the decrease of the process margin is prevented while maintaining the charge balance of the super junction structure.

Although the embodiment and modifications thereof are described above, the invention is not limited to these examples. For example, additions, deletions, or design modifications of components or appropriate combinations of the features of the embodiments appropriately made by one skilled in the art in regard to the embodiments or the modifications thereof described above are within the scope of the invention to the extent that the purport of the invention is included.

For example, although the first conductivity type is described as the n type and the second conductivity type is described as the p type in the embodiments and the modifications described above, the first conductivity type may be the p type and the second conductivity type may be the n type.

The formation method of the super junction structure is not limited to the methods described above. Various formation methods may be used such as a method of repeating ion implantation and epitaxial growth multiple times, a method of depositing a pillar layer into a trench after making the trench, a method of performing ion implantation into the side wall of a trench after making the trench, a method of performing ion implantation multiple times while changing the acceleration voltage, etc.

Although examples are described in the embodiments and the modifications recited above in which the element has a planar-type MOS gate structure, a trench-type MOS gate structure may be used.

Although examples are described in the embodiments and the modifications recited above in which a guard ring structure is used as the structure of the terminal region B, other than the guard ring structure, various structures such as a field plate structure, a RESURF structure, etc., may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device including a cell region configured to conduct current and a terminal region provided around the cell region, the device comprising:
a first semiconductor region of a first conductivity type;
a semiconductor pillar of the first conductivity type and a semiconductor pillar of a second conductivity type provided on the first semiconductor region in the cell region and arranged alternately along a first direction parallel to one major surface of the first semiconductor region;
a first main electrode provided on one other major surface side of the first semiconductor region;
a second semiconductor region of the second conductivity type provided in a surface of the semiconductor pillar of the second conductivity type;
a third semiconductor region of the first conductivity type provided on a surface side of the second semiconductor region;
a second main electrode connected to the second semiconductor region and the third semiconductor region; and
a control electrode provided with an interposed gate insulating film on the second semiconductor region, the third semiconductor region, and the semiconductor pillar of the first conductivity type,
a semiconductor pillar being provided in a stripe configuration extending in a second direction parallel to the one major surface of the first semiconductor region and orthogonal to the first direction, the semiconductor pillar provided in the stripe configuration being selected from the semiconductor pillar of the first conductivity type and the semiconductor pillar of the second conductivity type other than a semiconductor pillar most proximal to the terminal region,
the semiconductor pillar most proximal to the terminal region including a region having a relatively high impurity concentration and a region having a relatively low impurity concentration, the region having the high impurity concentration and the region having the low impurity concentration being provided alternately along the second direction.

2. The device according to claim 1, wherein a pitch along the second direction of the region having the high impurity concentration is equal to a pitch along the second direction of the region having the low impurity concentration.

3. The device according to claim 1, wherein a width along the first direction of the region having the high impurity concentration is equal to a width along the first direction of a semiconductor pillar adjacent to the semiconductor pillar most proximal to the terminal region.

4. The device according to claim 1, wherein an impurity amount of the semiconductor pillar most proximal to the terminal region is ½ of an impurity amount of a semiconductor pillar adjacent to the semiconductor pillar most proximal to the terminal region.

5. The device according to claim 1, wherein a guard ring is provided in the terminal region.

6. The device according to claim 5, wherein an equivalent potential ring electrode is provided in the terminal region on an outer side of the guard ring.

7. The device according to claim 1, further comprising a fourth semiconductor region of the second conductivity type provided between the first semiconductor region and the first main electrode.

8. The device according to claim 7, wherein a guard ring is provided in the terminal region.

9. The device according to claim 8, wherein an equivalent potential ring electrode is provided in the terminal region on an outer side of the guard ring.

10. The device according to claim 1, further comprising a fourth semiconductor region of the second conductivity type provided between the first semiconductor region and the first main electrode,
the first semiconductor region being electrically connected to the first main electrode at a portion of the fourth semiconductor region.

11. The device according to claim 10, wherein a guard ring is provided in the terminal region.

12. The device according to claim 11, wherein an equivalent potential ring electrode is provided in the terminal region on an outer side of the guard ring.

13. The device according to claim 1, wherein the control electrode is provided with an interposed insulating film inside a trench provided along a third direction perpendicular to the major surface in the semiconductor pillar of the first conductivity type, the second semiconductor region, and the third semiconductor region.

14. The device according to claim 13, wherein a guard ring is provided in the terminal region.

15. The device according to claim 14, wherein an equivalent potential ring electrode is provided in the terminal region on an outer side of the guard ring.

16. A method for manufacturing a semiconductor device including a cell region configured to conduct current and a terminal region provided around the cell region, the method comprising:
forming a first semiconductor region of a first conductivity type;
forming a high-resistance region on one major surface of the first semiconductor region;
forming a first impurity implantation region and a second impurity implantation region in the high-resistance region of the cell region, the first impurity implantation region including an implanted impurity of the first conductivity type, the second impurity implantation region including an implanted impurity of a second conductivity type, the first impurity implantation region and the second impurity implantation region being formed alternately along a first direction parallel to the one major surface of the first semiconductor region;
forming a semiconductor pillar of the first conductivity type and a semiconductor pillar of the second conductivity type by causing the first impurity implantation region to communicate along a direction perpendicular to the one major surface of the first semiconductor region and the second impurity implantation region to communicate along the direction perpendicular to the one major surface of the first semiconductor region by performing thermal diffusion after repeating the forming of the high-resistance region and the alternate forming of the first impurity implantation region and the second impurity implantation region;
forming a second semiconductor region of the second conductivity type selectively in a surface of the semiconductor pillar of the second conductivity type;
forming a third semiconductor region of the first conductivity type selectively in a surface of the second semiconductor region;
forming a control electrode with an interposed gate insulating film on the second semiconductor region, the third semiconductor region, and the semiconductor pillar of the first conductivity type;
forming a first main electrode on one other major surface side of the first semiconductor region; and
connecting a second main electrode to the second semiconductor region and the third semiconductor region,
the alternate forming of the first impurity implantation region and the second impurity implantation region including:
forming an impurity implantation region in a stripe configuration extending in a second direction parallel to the one major surface of the first semiconductor region and orthogonal to the first direction, the impurity implantation region having the stripe configuration being selected from the first impurity implantation region and the second impurity implantation region other than an impurity implantation region most proximal to the terminal region; and
forming a region having a relatively high impurity concentration and a region having a relatively low impurity concentration in the impurity implantation region most proximal to the terminal region, the region having the high impurity concentration and the region having the low impurity concentration being formed alternately along the first direction.
